(19) United States
(12) Patent Application Publication
(10) Pub. No.: US 2026/0059791 A1
(43) Pub. Date: Feb. 26, 2026

(54) MOSFET DEVICE BASED ON NIO GATE MODULATION AND ITS PREPARATION METHOD

(71) Applicant: Xidian University, Xi’an (CN)

(72) Inventors: Ling Yang, Xi’an (CN); Bin Hou, Xi’an (CN); Qingyuan Chang, Xi’an (CN); Xiaohua Ma, Xi’an (CN); Jiale Du, Xi’an (CN); Meng Zhang, Xi’an (CN); Mei Wu, Xi’an (CN); Hao Lu, Xi’an (CN); Yue Hao, Xi’an (CN)

(21) Appl. No.: 19/273,730

(22) Filed: Jul. 18, 2025

(30) Foreign Application Priority Data
Aug. 21, 2024 (CN) 202411153435X

(51) Int. Cl. H10D 30/63; H10D 30/01; H10D 62/85

(52) U.S. Cl. CPC H10D 30/635; H10D 30/025; H10D 62/8503

(57) ABSTRACT

A MOSFET device based on nickel oxide (NiO) gate modulation and its preparation method are provided. The MOSFET device includes a substrate layer, a first N-type gallium nitride (GaN) layer, a second N-type GaN layer, a P-type GaN layer, and a third N-type GaN layer disposed sequentially from bottom to top; gate stepped parts extending from both ends of an upper surface of the third N-type GaN layer to an interior of the second N-type GaN layer; gate structures extending from the upper surface of the third N-type GaN layer to bottoms of the gate stepped parts; a source recess, a source electrode, drain electrodes and NiO modulation layers extending from the bottoms of the gate stepped parts to an upper surface of the first N-type GaN layer. By setting the NiO modulation layers, a voltage withstand level of the MOSFET device is improved.

### CROSS-REFERENCE TO RELATED APPLICATION

This application claims priority to Chinese Patent Application No. 202411153435.X, filed Aug. 21, 2024, which is herein incorporated by reference in its entirety.

### TECHNICAL FIELD

The disclosure relates to the technical field of semiconductor, and more particularly to a metal-oxide-semiconductor field-effect transistor (MOSFET) device based on NIO gate modulation and its preparation method.

### BACKGROUND

Compared to silicon (Si)-based materials, gallium nitride (GaN) has excellent electrical properties such as wide band gap, high critical breakdown electric field, high saturation velocity, and good thermal conductivity. With the excellent electrical properties, GaN-based devices have higher breakdown voltages, and under same voltage withstand requirements, the GaN-based devices have lower on-resistance. Therefore, GaN has great potential in the field of high-voltage and high-power power electronics. For GaN planar devices used in high-voltage environments, to improve a breakdown voltage of a device, it is necessary to increase a source-drain distance and a gate-drain distance, so that the device has a larger withstand voltage space when blocked. However, this way increases a size of the device, resulting in a decrease in wafer utilization and an increase in cost per device.

GaN trench gate MOSFET uses a vertical drift layer to block breakdown voltage. As a result, the breakdown voltage of the device can be improved without requiring an increase in the size of the device, only by increasing a thickness of a drift region of the device. This approach effectively reduces the cost per device and improves the wafer utilization.

However, electric field concentration exists at a bottom corner of a trench of the GaN trench gate MOSFET, affecting a withstand voltage performance of the device.

### SUMMARY

To solve aforementioned problems in related art, the disclosure provides a MOSFET device based on NiO gate modulation and its preparation method. The technical problems to be solved by the disclosure are realized through the following technical solutions.

The MOSFET device based on NiO gate modulation is provided by the disclosure, including: a substrate layer, a first N-type gallium nitride (GaN) layer, a second N-type GaN layer, a P-type GaN layer, and a third N-type GaN layer disposed sequentially from bottom to top; gate stepped parts, gate structures, a source recess, a source electrode, drain electrodes, and NiO modulation layers.

The gate stepped parts extend from both ends of an upper surface of the third N-type GaN layer to an interior of the second N-type GaN layer.

The gate structures extend from the upper surface of the third N-type GaN layer to bottoms of the gate stepped parts.

The source recess extends from the upper surface of the third N-type GaN layer to a lower surface of the third N-type GaN layer.

The source electrode is disposed in the source recess.

The drain electrodes are disposed on an upper surface of the first N-type GaN layer on both sides of the second N-type GaN layer and spaced from the second N-type GaN layer.

The NiO modulation layers extend from the bottoms of the gate stepped parts to the upper surface of the first N-type GaN layer.

In an embodiment, the source electrode extends from the source recess to the upper surface of the third N-type GaN layer and is spaced from the gate structures.

In an embodiment, the gate structures include gate dielectric layers and gate electrodes. The gate dielectric layers extend from the upper surface of the third N-type GaN layer to the bottoms of the gate stepped parts. The gate electrodes are disposed on surfaces of the gate dielectric layers.

In an embodiment, a material of the substrate layer includes one or more selected from the group consisting of Si, silicon carbide (SiC) and sapphire. A material of the gate dielectric layers includes aluminum oxide (Al₂O₃). Materials of the gate electrodes include nickel (Ni) and aurum (Au) (i.e., Ni/Au). Materials of the source electrode include titanium (Ti) and aluminum (Al) and Ni and Au (i.e., Ti/Al/Ni/Au). Materials of the drain electrodes include Ti and Al and Ni and Au (i.e., Ti/Al/Ni/Au).

In an embodiment, a length of each gate structure at the bottom of each gate stepped part is in a range of 0.1 micrometers (μm) to 6 μm.

In an embodiment, a length of each NiO modulation layer at the bottom of each gate stepped part is in a range of 2 μm to 8 μm. A length of each NiO modulation layer at the upper surface of the first N-type GaN layer is in a range of 5 μm to 8 μm. A distance between each drain electrode and the second N-type GaN layer is in a range of 7 μm to 10 μm.

In an embodiment, a doping concentration of the first N-type GaN layer is in a range of 1.0×10¹⁹ per cubic centimeter (cm⁻³) to 1×10²⁰ cm⁻³, and a thickness of the first N-type GaN layer is in a range of 1 μm to 2 μm. A doping concentration of the second N-type GaN layer is in a range of 1.0×10¹⁵ cm⁻³ to 2×10¹⁶ cm⁻³, and a thickness of the second N-type GaN layer is in a range of 3 μm to 5 μm. A doping concentration of the P-type GaN layer is in a range of 1.0×10¹⁷ cm⁻³ to 1×10¹⁸ cm⁻³, and a thickness of the P-type GaN layer is in a range of 200 nanometers (nm) to 350 nm. A doping concentration of the third N-type GaN layer is in a range of 1.0×10¹⁹ cm⁻³ to 1×10²⁰ cm⁻³, and a thickness of the third N-type GaN layer is in a range of 200 nm to 300 nm.

In an embodiment, a doping type of each NiO modulation layer is P-type, a doping concentration of each NiO modulation layer is in a range of 1.0×10¹⁵ cm⁻³ to 1×10¹⁸ cm⁻³, and a thickness of each NiO modulation layer is in a range of 100 nm to 200 nm.

The preparation method of the MOSFET device based on NiO gate modulation is provided by the disclosure, including the following steps:
S1: acquiring the substrate layer, the first N-type GaN layer, the second N-type GaN layer, the P-type GaN layer, and the third N-type GaN layer disposed sequentially from bottom to top;
S2: etching both ends of the third N-type GaN layer to form the gate stepped parts extending from the both ends of the upper surface of the third N-type GaN layer to the interior of the second N-type GaN layer;
S3: preparing the gate structures on the upper surface of the third N-type GaN layer, side walls and the bottoms of the gate stepped parts;
S4: etching the upper surface of the third N-type GaN layer to form the source recess extending from the upper surface of the third N-type GaN layer to the lower surface of the third N-type GaN layer;
S5: preparing the source electrode in the source recess; and preparing drain electrodes on the upper surface of the first N-type GaN layer on both sides of the second N-type GaN layer, in which the drain electrodes are spaced from the second N-type GaN layer; and
S6: preparing NiO modulation layers on the bottoms of the gate stepped parts, a side surface of the second N-type GaN layer and the upper surface of the first N-type GaN layer.

In an embodiment, the step S6 includes:
sputtering, by using a magnetron sputtering process, P-type NiO with a thickness in a range of 100 nm to 200 nm on the bottoms of the gate stepped parts, the side surface of the second N-type GaN layer and the upper surface of the first N-type GaN layer to obtain the NiO modulation layers, in which a target material of the magnetron sputtering process is NiO and working gases of the magnetron sputtering process are oxygen (O₂) and argon (Aᵣ).

Compared with technologies in related art, the disclosure has the following beneficial effects.

The MOSFET device based on NiO gate modulation provided by the disclosure uses the NiO modulation layers to deplete interface states of the second N-type GaN layer and electrons on a surface of the second N-type GaN layer, to thereby generate a depletion region and widen an electric field distribution range of the MOSFET device, therefore reducing a peak electric field strength of the MOSFET device and improving a withstand voltage level of the MOSFET device.

### BRIEF DESCRIPTION OF DRAWINGS

FIG. 1 illustrates a schematic structural diagram of a MOSFET device based on NiO gate modulation according to an embodiment of the disclosure.

FIG. 2A through FIG. 2I illustrate schematic step diagrams of a preparation method of the MOSFET device based on NiO gate modulation according to the embodiment of the disclosure.

### DESCRIPTION OF REFERENCE NUMERALS

1: substrate layer; 2: first N-type GaN layer; 3: second N-type GaN layer; 4: P-type GaN layer; 5: third N-type GaN layer; 6: gate dielectric layer; 7: gate electrode; 8: source electrode; 9: drain electrode; 10: NiO modulation layer; 11: gate stepped part; 12: source recess.

### DETAILED DESCRIPTION OF EMBODIMENTS

The disclosure will be further described in detail with reference to specific embodiments, but embodiments of the disclosure are not limited thereto.

### Embodiment 1

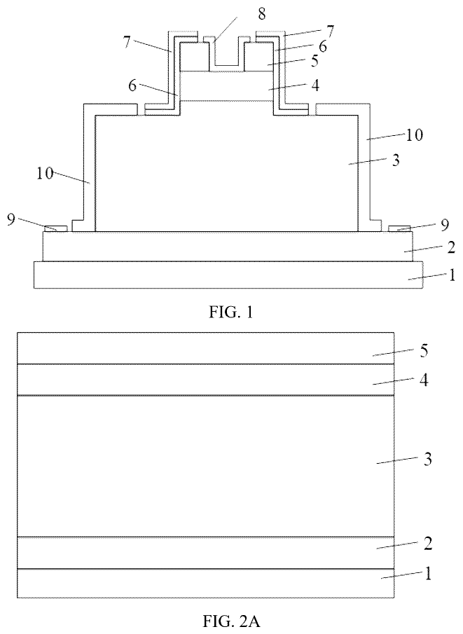

As illustrated in FIG. 1, FIG. 1 illustrates a schematic structural diagram of a MOSFET device based on NiO gate modulation according to an embodiment of the disclosure.

The MOSFET device based on NiO gate modulation provided by the disclosure includes a substrate layer 1, a first N-type GaN layer 2, a second N-type GaN layer 3, a P-type GaN layer 4, a third N-type GaN layer 5, gate stepped parts 11, gate structures, a source recess 12, a source electrode 8, drain electrodes 9 and NiO modulation layers 10. The substrate layer 1, the first N-type GaN layer 2, the second N-type GaN layer 3, the P-type GaN layer 4, and the third N-type GaN layer 5 are disposed sequentially from bottom to top. The gate stepped parts 11 extend from both ends of an upper surface of the third N-type GaN layer 5 to an interior of the second N-type GaN layer 3. The gate structures extend from the upper surface of the third N-type GaN layer 5 to bottoms of the gate stepped parts 11. The source recess 12 extends from the upper surface of the third N-type GaN layer 5 to a lower surface of the third N-type GaN layer 5. The source electrode 8 is disposed in the source recess 12. The drain electrodes 9 are disposed on an upper surface of the first N-type GaN layer 2 on both sides of the second N-type GaN layer 3 and is spaced from the second N-type GaN layer 3. The NiO modulation layers 10 extend from the bottoms of the gate stepped parts 11 to the upper surface of the first N-type GaN layer 2.

In the embodiment, the gate structures extend from the upper surface of the third N-type GaN layer 5 through side walls of the gate stepped parts 11 to the bottoms of the gate stepped parts 11. A depth of each gate stepped part 11 is greater than or equal to a sum of thicknesses of the P-type GaN layer 4 and the third N-type GaN layer 5. It should be understood that, the side wall of each gate stepped part 11 is a side surface of the third N-type GaN layer 5 and a side surface of the P-type GaN layer 4, and the bottom of each gate stepped part 11 is the upper surface of the third N-type GaN layer 5. The NiO modulation layers 10 extend from the bottoms of the gate stepped parts 11 through a side surface of the second N-type GaN layer 3 to the upper surface of the first N-type GaN layer 2. The gate structures are disposed on ends of the gate stepped parts 11 facing toward the third N-type GaN layer 5. The NiO modulation layers 10 extend from ends of the gate stepped parts 11 facing away from the third N-type GaN layer 5 to the upper surface of the first N-type GaN layer 2 between the drain electrodes 9 and the second N-type GaN layer 3. A device (i.e., a MOSFET) provided in this embodiment adopts an axial symmetry layout, with an axis of symmetry being a central axis of the device, that is, central axes of the substrate layer 1, the first N-type GaN layer 2, the second N-type GaN layer 3, the P-type GaN layer 4, and the third N-type GaN layer 5. The source electrode 8 is disposed on a center part on top of the device. The gate stepped parts 11 two in quantity are symmetrically set on left and right sides of the device. Correspondingly, the gate structures, the drain electrodes 9, and the NiO modulation layers 10 are all two in quantity, and are all symmetrically set on the left and right sides of the device. In this embodiment, PN junctions are formed between the NiO modulation layers 10 and the second N-type GaN layer 3 to deplete interface states of the second N-type GaN layer 3 and electrons near a surface of the second N-type GaN layer 3, to thereby generate a depletion region, therefore making electric field distribution widen from the gate structures of the device to both sides of the device, reducing an electric field peak value at the gate structures, alleviating an electric field crowding phenomenon near the gate structures, preventing premature breakdown, and improving a withstand voltage level of the device.

In the embodiment, the source electrode 8 extends from the source recess 12 to the upper surface of the third N-type GaN layer 5 and is spaced from the gate structures. A length of each gate structure at the bottom of each gate stepped part 11 is in a range of 0.1 μm to 6 μm. A length of each NiO modulation layer 10 at the bottom of each gate stepped part 11 is in a range of 2 μm to 8 μm, and a length of each NiO modulation layer 10 at the upper surface of the first N-type GaN layer 2 is in a range of 5 μm to 8 μm. A distance between the drain electrodes 9 and the second N-type GaN layer 3 is in a range of 7 μm to 10 μm.

In the embodiment, a length of each gate stepped part 11 is in a range of 2 μm to 10 μm. A distance between each NiO modulation layer 10 on each gate stepped part 11 and a corresponding one of the gate structures is in a range of 0 μm to 2 μm. It should be understood that, the device provided in this embodiment adopts the axial symmetry layout with gate stepped parts 11 two in quantity. Correspondingly, the gate structures, the drain electrodes 9, and the NiO modulation layers 10 are all two in quantity. In the embodiment, all lengths are lengths of single structures, and all distances are distances between two structures on one side of the device. In the embodiment, the length of each gate stepped part 11 is in a range of 2 μm to 10 μm, and a total length of the gate stepped parts 11 on both the left and right sides of the device is in a range of 4 μm to 20 μm. The length of each NiO modulation layer 10 on the left side or right side of the device at the bottom of each gate stepped part 11 is in a range of 2 μm to 8 μm, and a total length of the NiO modulation layers 10 on both the left and right sides of the device at the bottoms of the gate stepped parts 11 is in a range of 4 μm to 16 μm. A distance between the drain electrode 9 on the left side of the device and a left side wall of the second N-type GaN layer 3 is in a range of 7 μm to 10 μm, and a distance between the drain electrode 9 on the right side of the device and a right side wall of the second N-type GaN layer 3 is in a range of 7 μm to 10 μm.

In the embodiment, the gate structures include gate dielectric layers 6 and gate electrodes 7. The gate dielectric layers 6 extend from the upper surface of the third N-type GaN layer 5 to the bottoms of the gate stepped parts 11. The gate electrodes 7 are disposed on surfaces of the gate dielectric layers 6.

In the embodiment, a material of the substrate layer 1 includes one or more selected from the group consisting of Si, SiC and sapphire. A doping concentration of the first N-type GaN layer 2 is in a range of 1.0×10¹⁹ cm⁻³ to 1×10²⁰ cm⁻³, and a thickness of the first N-type GaN layer 2 is in a range of 1 μm to 2 μm. A doping concentration of the second N-type GaN layer 3 is in a range of 1.0×10¹⁵ cm⁻³ to 2×10¹⁶ cm⁻³, and a thickness of the second N-type GaN layer 3 is in a range of 3 μm to 5 μm. A doping concentration of the P-type GaN layer 4 is in a range of 1.0×10¹⁷ cm⁻³ to 1×10¹⁸ cm⁻³, and a thickness of the P-type GaN layer 4 is in a range of 200 nm to 350 nm. A doping concentration of the third N-type GaN layer 5 is in a range of 1.0×10¹⁹ cm⁻³ to 1×10²⁰ cm⁻³, and a thickness of the third N-type GaN layer 5 is in a range of 200 nm to 300 nm. A material of the gate dielectric layers 6 includes Al₂O₃. Materials of the gate electrodes 7 include Ni/Au. Materials of the source electrode 8 include Ti/Al/Ni/Au. Materials of the drain electrodes 9 include Ti/Al/Ni/Au. A doping type of each NiO modulation layer 10 is P-type, a doping concentration of each NiO modulation layer 10 is in a range of 1.0×10¹⁵ cm⁻³ to 1×10¹⁸ cm⁻³, and a thickness of each NiO modulation layer 10 is in a range of 100 nm to 200 nm. Doping ions of the first N-type GaN layer 2, the second N-type GaN layer 3 and the third N-type GaN layer 5 are all Si ions, and doping ions of the P-type GaN layer 4 are magnesium (Mg) ions.

In an embodiment, Ni/Au refers to Ni and Au stacked from bottom to top, in which a thickness of the Ni is in a range of 30 nm to 50 nm, and a thickness of the Au is in a range of 300 nm to 450 nm. Ti/Al/Ni/Au refers to Ti, Al, Ni, and Au stacked sequentially from bottom to top, in which a thickness of the Ti is in a range of 20 nm to 30 nm, a thickness of the Al is in a range of 140 nm to 180 nm, a thickness of the Ni is in a range of 40 nm to 60 nm, and a thickness of the Au is in a range of 30 nm to 50 nm.

In the embodiment, the device further includes device isolation regions. The device isolation regions are disposed on both sides of the first N-type GaN layer 2 with depths in a range of 1 μm to 2 μm.

In an embodiment, the device provided in the disclosure has two PN junctions. The third N-type GaN layer 5 and the P-type GaN layer 4 form a J1 junction, and the P-type GaN layer 4 and the second N-type GaN layer 3 form a J2 junction. When no bias voltage is applied to the gate electrodes 7, the source electrode 8, and the drain electrodes 9 of the device, that is, when a gate voltage Vgate, a source voltage Vsource, and a drain voltage Vdrain are all 0, an N-type inversion channel inside the MOSFET is not turned on, and both the J1 junction and the J2 junction are in a zero-bias state, so no current is generated inside the device.

When no bias voltage is applied to the gate electrodes 7 and the source electrode 8 of the device and a forward voltage is applied to the drain electrode 9 (Vdrain>0, Vsource=0, Vgate=0), the J2 junction formed by the P-type GaN layer 4 and the second N-type GaN layer 3 is in a reverse-biased state. The second N-type GaN layer 3, as a drift region of the device, is of low doping concentration, and the P-type GaN layer 4 is of high doping concentration. In this way, when the J2 junction is in the reverse-biased state, a depletion layer mainly extends to the second N-type GaN layer 3 with low doping concentration. Therefore, a breakdown voltage of the MOSFET largely depends on structural parameters of the second N-type GaN layer 3, such as a thickness and doping concentration of the drift region. In the embodiment, the doping concentration of the second N-type GaN layer 3 is in a range of 1.0×10¹⁵ cm⁻³ to 2×10¹⁶ cm⁻³, and the thickness of the second N-type GaN layer 3 is in a range of 3 μm to 5 μm, so as to ensure that the device has a high breakdown voltage in the reverse-biased state.

When no bias voltage is applied to the source electrode 8 of the device and forward voltages are applied to the gate electrodes 7 and the drain electrodes 9 (Vdrain >0, Vsource=0, Vth>Vgate>0), where Vth refers to a threshold voltage when the device is turned on, when Vgate is greater than 0 but less than Vth, holes on a surface of the P-type GaN layer 4 are driven by the gate voltage to be transferred to an interior of the P-type GaN layer 4, and some negatively charged acceptor Mg ions appear on a channel surface. At this time, a conduction channel between the source electrode 8 and the drain electrode 9 is still closed, and the device is in a blocking state. As Vgate continues to increase, when Vgate is greater than Vth (Vdrain>0, Vsource=0, Vgate>Vth), with a downward bending of an energy band on the surface of the P-type GaN layer 4, a large number of minority carriers (electrons) appear on the side surface of the P-type GaN layer 4, thereby forming an electron accumulation layer; that is, a strong inversion state appears. Meanwhile, a type of a part of the P-type GaN layer 4 facing toward the gate electrode 7 is equivalent to N-type, therefore forming a current path between the third N-type GaN layer 5 and the second N-type GaN layer 3. Therefore, under an action of the drain electrodes 9 with a forward-bias state, the electrons enter an inversion channel from the third N-type GaN layer 5, then flow into the second N-type GaN layer 3 below along a direction perpendicular to the substrate layer 1, and are finally collected by the drain electrodes 9, thereby forming output current between the source electrode 8 and the drain electrodes 9.

The MOSFET device based on NiO gate modulation provided in the embodiment uses the NiO modulation layers 10 to deplete interface states of the second N-type GaN layer 3 and electrons on the surface of the second N-type GaN layer 3, to thereby generate a depletion region and widen an electric field distribution range of the device, therefore reducing a peak electric field strength of the device, and improving the withstand voltage level of the device.

### Embodiment 2

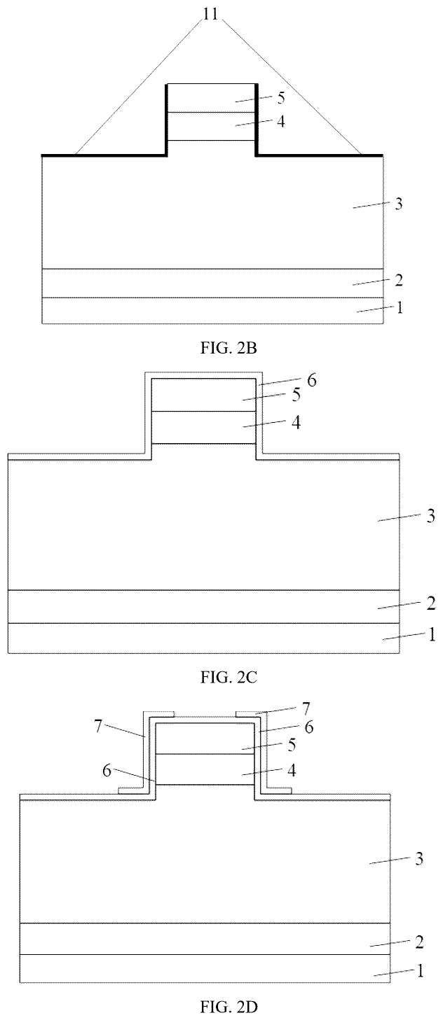

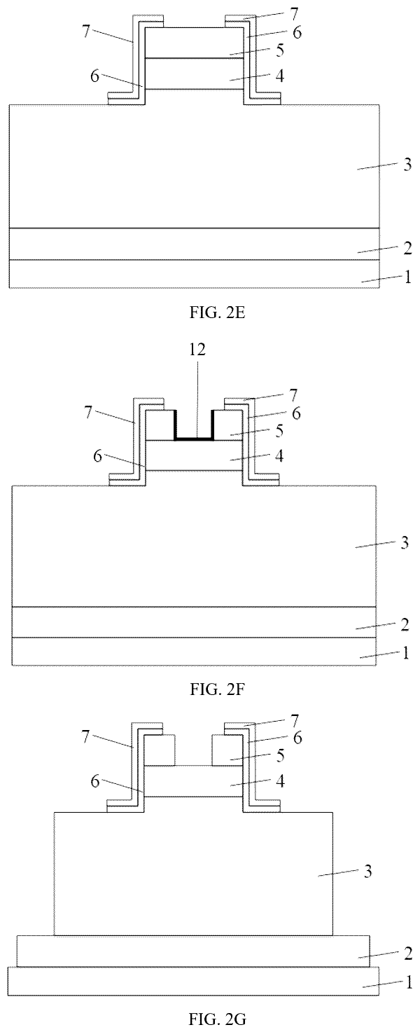

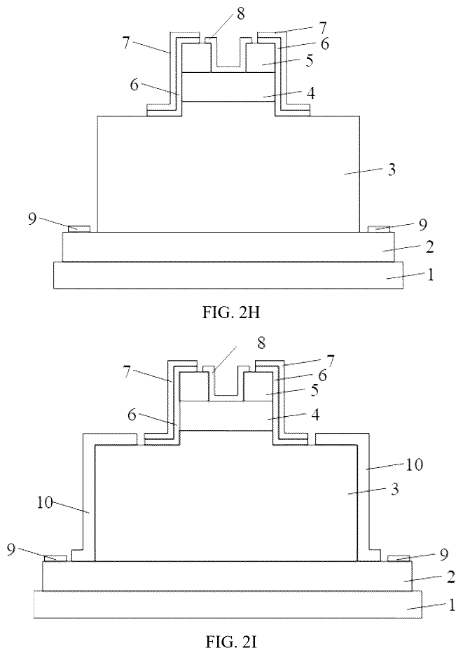

As illustrated in FIG. 2A through FIG. 2I, FIG. 2A through FIG. 2I illustrate schematic step diagrams of a preparation method of the MOSFET device based on NiO gate modulation according to the embodiment of the disclosure.

The preparation method of the MOSFET device based on NiO gate modulation provided in the disclosure includes the following steps.
S1: the substrate layer 1, the first N-type GaN layer 2, the second N-type GaN layer 3, the P-type GaN layer 4, and the third N-type GaN layer 5 disposed sequentially from bottom to top are acquired.

In the embodiment, as illustrated in FIG. 2A, a material of the substrate layer 1 includes one or more selected from the group consisting of Si, SiC and sapphire. The doping concentration of the first N-type GaN layer 2 is in the range of 1.0×10¹⁹ cm⁻³ to 1×10²⁰ cm⁻³, and the thickness of the first N-type GaN layer 2 is in the range of 1 μm to 2 μm. The doping concentration of the second N-type GaN layer 3 is in the range of 1.0×10¹⁵ cm⁻³ to 2×10¹⁶ cm⁻³, and the thickness of the second N-type GaN layer 3 is in the range of 3 μm to 5 μm. The doping concentration of the P-type GaN layer 4 is in the range of 1.0×10¹⁷ cm⁻³ to 1×10¹⁸ cm⁻³, and the thickness of the P-type GaN layer 4 is in the range of 200 nm to 350 nm. The doping concentration of the third N-type GaN layer 5 is in the range of 1.0×10¹⁹ cm⁻³ to 1×10²⁰ cm⁻³, and the thickness of the third N-type GaN layer 5 is in the range of 200 nm to 300 nm.
S2: both ends of the third N-type GaN layer 5 are etched to form the gate stepped parts 11 extending from the both ends of the upper surface of the third N-type GaN layer 5 to the interior of the second N-type GaN layer 3.

In the embodiment, as illustrated in FIG. 2B, both ends of the third N-type GaN layer 5 are etched by inductively coupled plasma (ICP) process. An etching gas is boron trichloride (BCl₃)/chlorine (Cl₂), and an etching depth is in a range of 600 nm to 900 nm, so as to completely etch and remove both ends of the P-type GaN layer 4 and the third N-type GaN layer 5. In this way, the bottoms of the gate stepped parts 11 are located inside the second N-type GaN layer 3. In this embodiment, the length of each gate stepped part 11 is in a range of 2 μm to 10 μm.
S3: gate structures are prepared on the upper surface of the third N-type GaN layer 5, side walls and bottoms of the gate stepped parts 11.

In the embodiments, the step S3 includes the following steps.
S301: as illustrated in FIG. 2C, by using atomic layer deposition (ALD) process, Al₂O₃ with a thickness in a range of 45 nm to 55 nm is grown on the bottoms and side walls of the gate stepped parts 11 and a surface of the third N-type GaN layer 5 to form the gate dielectric layers 6. A length of each gate dielectric layer 6 at the bottom of each gate stepped part 11 is in a range of 0.1 μm to 6 μm.
S302: as illustrated in FIG. 2D, Ni/Au is sputtered on surfaces of the gate dielectric layers 6 at both ends of the upper surface of the third N-type GaN layer 5 and on surfaces of the gate dielectric layers 6 at the bottoms and the side walls of the gate stepped parts 11 to form the gate electrodes 7. Where, the thickness of Ni is in the range of 30 nm to 50 nm, and the thickness of Au is in the range of 300 nm to 450 nm.
S303: as illustrated in FIG. 2E, parts of the gate dielectric layers 6 uncovered by the gate electrodes 7 are removed by using ICP etching. An etching gas is carbon tetrafluoride gas (CF₄). The gate dielectric layers 6 and the gate electrodes 7 form the gate structures.
S4: the upper surface of the third N-type GaN layer 5 is etched to form the source recess 12 extending from the upper surface of the third N-type GaN layer 5 to the lower surface of the third N-type GaN layer 5.

In the embodiment, as illustrated in FIG. 2F, a center of the upper surface of the third N-type GaN layer 5 is etched to form the source recess 12 extending from the upper surface of the third N-type GaN layer 5 to the lower surface of the third N-type GaN layer 5. An etching gas is BCl₃/Cl₂, an etching depth is in a range of 2000 nm to 300 nm.
S5: the source electrode 8 is prepared in the source recess 12; and the drain electrodes 9 are prepared on the upper surface of the first N-type GaN layer 2 on both sides of the second N-type GaN layer 3. The drain electrodes 9 are spaced from the second N-type GaN layer 3. The distance between the drain electrodes 9 and the second N-type GaN layer 3 is in the range of 7 μm to 10 μm.

In the embodiment, as illustrated in FIG. 2G, both ends of the second N-type GaN layer 3 are etched and removed to define a drain groove by using the ICP process, and both ends of the first N-type GaN layer 2 are etched to define the device isolation regions by using the ICP process. As illustrated in FIG. 2H, Ti/Al/Ni/Au are evaporated in the source recess 12 and the drain groove. The thickness of the Ti is in the range of 20 nm to 30 nm, the thickness of the Al is in the range of 140 nm to 180 nm, the thickness of the Ni is in the range of 40 nm to 60 nm, and the thickness of the Au is in the range of 30 nm to 50 nm. In the embodiments, the distance between each drain electrode 9 and the second N-type GaN layer 3 is in the range of 7 μm to 10 μm. An etching depth of the drain groove is in a range of 4 μm to 6 μm. An etching depth of each device isolation region is in a range of 1 μm to 2 μm.
S6: the NiO modulation layers 10 are prepared on the bottoms of the gate stepped parts 11, the side surface of the second N-type GaN layer 3 and the upper surface of the first N-type GaN layer 2.

In the embodiment, the step S6 specifically includes steps as follows.

By using a magnetron sputtering process, P-type NiO with a thickness in a range of 100 nm to 200 nm is sputtered on the bottoms of the gate stepped parts 11, the side surface of the second N-type GaN layer 3, and the upper surface of the first N-type GaN layer 2 to obtain the NiO modulation layers 10, in which a target material of the magnetron sputtering process is NiO and working gases of the magnetron sputtering process are O₂ and Aᵣ. In an embodiment, a proportion of O₂ in the working gas is in a range of 0% to 66%. By adjusting the proportion of O₂ in the working gases, a doping concentration of the P-type NiO grown is made to be in a range of 1.0×10¹⁵ cm⁻³ to 1×10¹⁸ cm⁻³. The length of each NiO modulation layer 10 at the bottom of each gate stepped part 11 is in the range of 2 μm to 8 μm. The distance between each NiO modulation layer 10 on each gate stepped part 11 and the corresponding one of the gate structures is in the range of 0 μm to 2 μm. The length of each NiO modulation layer 10 at the upper surface of the first N-type GaN layer 2 is in the range of 5 μm to 8 μm.

The preparation method of MOSFET device based on NiO gate modulation provided in the embodiment, by preparing the NiO modulation layers 10 on the bottoms of the gate stepped parts 11, the side surface of the second N-type GaN layer 3 and the upper surface of the first N-type GaN layer 2 to deplete interface states of the second N-type GaN layer 3 and electrons on the surface of the second N-type GaN layer 3, generates the depletion region and widens the electric field distribution range of the device, therefore reducing the peak electric field strength of the device and improving the withstand voltage level of the device. Moreover, in the embodiment, the NiO modulation layers 10 are prepared by using the magnetron sputtering process, so that a process is simple, production cost is low, and production requirement is met.

Above content is a further detailed description of the disclosure combined with specific embodiments, and it cannot be considered that the specific implementation of the disclosure is limited to these descriptions. For those skilled in the art, several simple deductions or substitutions can be made without departing from a concept of the present invention. All the deductions or substitutions fall within a scope of protection of the disclosure.

What is claimed is:

1. A metal-oxide-semiconductor field-effect transistor (MOSFET) device based on nickel oxide (NiO) gate modulation, comprising:
a substrate layer (1), a first N-type gallium nitride (GaN) layer (2), a second N-type GaN layer (3), a P-type GaN layer (4), and a third N-type GaN layer (5) disposed sequentially from bottom to top;
gate stepped parts (11), extending from both ends of an upper surface of the third N-type GaN layer (5) to an interior of the second N-type GaN layer (3);
gate structures, extending from the upper surface of the third N-type GaN layer (5) to bottoms of the gate stepped parts (11);
a source recess (12), extending from the upper surface of the third N-type GaN layer (5) to a lower surface of the third N-type GaN layer (5);
a source electrode (8), disposed in the source recess (12);
drain electrodes (9), disposed on an upper surface of the first N-type GaN layer (2) on both sides of the second N-type GaN layer (3), and spaced from the second N-type GaN layer (3); and
NiO modulation layers (10), extending from the bottoms of the gate stepped parts (11) to the upper surface of the first N-type GaN layer (2).

2. The MOSFET device based on NiO gate modulation as claimed in claim 1, wherein the source electrode (8) extends from the source recess (12) to the upper surface of the third N-type GaN layer (5) and is spaced from the gate structures.

3. The MOSFET device based on NiO gate modulation as claimed in claim 1, wherein the gate structures comprise gate dielectric layers (6) and gate electrodes (7);
the gate dielectric layers (6) extend from the upper surface of the third N-type GaN layer (5) to the bottoms of the gate stepped parts (11); and
the gate electrodes (7) are disposed on surfaces of the gate dielectric layers (6).

4. The MOSFET device based on NiO gate modulation as claimed in claim 3, wherein a material of the substrate layer (1) comprises one or more selected from the group consisting of silicon, silicon carbide and sapphire;
a material of the gate dielectric layers (6) comprises aluminum oxide;
materials of the gate electrodes (7) comprise nickel (Ni) and aurum (Au);
materials of the source electrode (8) comprise titanium (Ti), aluminum (Al), Ni, and Au; and
materials of the drain electrodes (9) comprise Ti, Al, Ni, and Au.

5. The MOSFET device based on NiO gate modulation as claimed in claim 1, wherein a length of each gate structure at the bottom of each gate stepped part (11) is in a range of 0.1 micrometers (μm) to 6 μm.

6. The MOSFET device based on NiO gate modulation as claimed in claim 1, wherein a length of each NiO modulation layer (10) at the bottom of each gate stepped part (11) is in a range of 2 μm to 8 μm;
a length of each NiO modulation layer (10) at the upper surface of the first N-type GaN layer (2) is in a range of 5 μm to 8 μm; and
a distance between each drain electrode (9) and the second N-type GaN layer (3) is in a range of 7 μm to 10 μm.

7. The MOSFET device based on NiO gate modulation as claimed in claim 1, wherein a doping concentration of the first N-type GaN layer (2) is in a range of 1.0×10¹⁹ per cubic centimeter (cm⁻³) to 1×10²⁰ cm⁻³, and a thickness of the first N-type GaN layer (2) is in a range of 1 μm to 2 μm;
a doping concentration of the second N-type GaN layer (3) is in a range of 1.0×10¹⁵ cm⁻³ to 2×10¹⁶ cm⁻³, and a thickness of the second N-type GaN layer (3) is in a range of 3 μm to 5 μm;
a doping concentration of the P-type GaN layer (4) is in a range of 1.0×10¹⁷ cm⁻³ to 1×10¹⁸ cm⁻³, and a thickness of the P-type GaN layer (4) is in a range of 200 nanometers (nm) to 350 nm; and
a doping concentration of the third N-type GaN layer (5) is in a range of 1.0×10¹⁹ cm⁻³ to 1×10²⁰ cm⁻³, and a thickness of the third N-type GaN layer (5) is in a range of 200 nm to 300 nm.

8. The MOSFET device based on NiO gate modulation as claimed in claim 1, wherein a doping type of each NiO modulation layer (10) is P-type, a doping concentration of each NiO modulation layer (10) is in a range of 1.0×10¹⁵ cm⁻³ to 1×10¹⁸ cm⁻³, and a thickness of each NiO modulation layer (10) is in a range of 100 nm to 200 nm.

9. A preparation method of a MOSFET device based on NiO gate modulation, comprising the following steps:
S1: acquiring a substrate layer (1), a first N-type GaN layer (2), a second N-type GaN layer (3), a P-type GaN layer (4), and a third N-type GaN layer (5) disposed sequentially from bottom to top;
S2: etching both ends of the third N-type GaN layer (5) to form gate stepped parts (11) extending from the both ends of an upper surface of the third N-type GaN layer (5) to an interior of the second N-type GaN layer (3);
S3: preparing gate structures on the upper surface of the third N-type GaN layer (5), side walls and bottoms of the gate stepped parts (11);
S4: etching the upper surface of the third N-type GaN layer (5) to form a source recess

(12) extending from the upper surface of the third N-type GaN layer (5) to a lower surface of the third N-type GaN layer (5);
S5: preparing a source electrode (8) in the source recess (12); and preparing drain electrodes (9) on an upper surface of the first N-type GaN layer (2) on both sides of the second N-type GaN layer (3), wherein the drain electrodes (9) are spaced from the second N-type GaN layer (3); and
S6: preparing NiO modulation layers (10) on the bottoms of the gate stepped parts (11), a side surface of the second N-type GaN layer (3) and the upper surface of the first N-type GaN layer (2).

10. The preparation method of the MOSFET device based on NiO gate modulation as claimed in claim 9, wherein the step S6 comprises:
sputtering, by using a magnetron sputtering process, P-type NiO with a thickness in a range of 100 nm to 200 nm on the bottoms of the gate stepped parts (11), the side surface of the second N-type GaN layer (3), and the upper surface of the first N-type GaN layer (2) to obtain the NiO modulation layers (10); and
wherein a target material of the magnetron sputtering process is NiO, and working gases of the magnetron sputtering process are oxygen and argon.
